(19) United States
(12) Patent Application Publication
(10) Pub. No.: US 2018/0073745 A1
(43) Pub. Date: Mar. 15, 2018

(54) VARIABLE HEIGHT DOWNDRAFT BUILT INTO COOKING DEVICE

(71) Applicant: Electrolux Home Products, Inc., Charlotte, NC (US)

(72) Inventors: Douglas Chris Norman, Hendersonville, TN (US); Jonathan Wright, Goodletsville, TN (US); Lloyd Smith, Charleston, TN (US)

(21) Appl. No.: 15/690,137

(22) Filed: Aug. 29, 2017

Related U.S. Application Data
(60) Provisional application No. 62/394,346, filed on Sep. 14, 2016.

(51) Int. Cl. F24C 15/20; F24F 7/04; G01R 33/07

(52) U.S. Cl. CPC F24C 15/2042; F24C 15/2085; F24F 2007/001; F24F 7/04; G01R 33/072; F24C 15/2092

(57) ABSTRACT

A household appliance including a heating element at an upper surface of the appliance, and a variable height downdraft vent assembly movable relative to the upper surface. The vent assembly includes a duct defining a flow passage between an upper end and a lower end thereof. The duct is movable in a vertical direction relative to the upper surface of the appliance. A drive assembly is provided for engaging the duct to position the upper end of the duct at a user-selected variable height relative to the upper surface of the appliance.

### FIELD OF THE INVENTION

The following description relates generally to cooktops and, more specifically, to a variable height downdraft assembly for a cooktop.

### BACKGROUND OF THE INVENTION

Cooktops or other appliances include a plurality of heating elements for cooking food items. The food items are usually placed in pots or pans of varying height. In situations where an over-head vent hood is not feasible or desired, cooktops often utilize a downdraft system. However, in many instances, the downdraft system is large and bulky. In situations where the downdraft system is movable, the system tends to be moveable into only two positions, i.e., a fully extended, operating position or a fully retracted, stored position, relative to an upper surface of the cooktop.

It is desirable to have a downdraft vent system where the height of the downdraft relative to an upper surface of a cooktop can be varied by a user to place an inlet of the system at an optimal height based on a height of the pots/pans disposed on the cooktop.

### SUMMARY OF THE INVENTION

A household appliance including a heating element at an upper surface of the appliance, and a variable height downdraft vent assembly movable relative to the upper surface of the appliance. The vent assembly includes a duct defining a flow passage between an upper end and a lower end thereof. The duct is movable in a vertical direction relative to the upper surface of the appliance. A drive assembly is provided for engaging the duct to position the upper end of the duct at a user-selected variable height relative to the upper surface of the appliance.

### BRIEF DESCRIPTION OF THE DRAWINGS

Preferred embodiments are disclosed and described in detail herein with reference to the accompanying drawings which form a part hereof, wherein:

FIG. 1 is a perspective view showing a cooktop having a variable height downdraft assembly in a fully retracted position;

FIG. 2 is a perspective view of the embodiment shown in FIG. 1, showing the variable height downdraft assembly in an intermediate position;

FIG. 3 is a perspective view of the embodiment shown in FIG. 1, showing the variable height downdraft assembly in a fully extended position;

FIG. 4 is a sectional view of the embodiment shown in FIG. 1 taken along line 4-4 showing the variable height downdraft assembly in its fully retracted position;

FIG. 5 is a sectional view as in FIG. 4, showing the variable height downdraft assembly in the fully extended position;

FIG. 6 is a sectional view of the embodiment shown in FIG. 4 taken along line 6-6;

FIG. 7 is a sectional view of the embodiment shown in FIG. 4 taken along line 7-7;

FIG. 8 is an enlarged elevational view taken along line 8-8 of FIG. 5 of the inlet end of the variable height downdraft assembly shown in FIG. 1;

FIG. 9 is a bottom perspective view of the embodiment shown in FIG. 1, showing an exhaust assembly of the variable height downdraft assembly; and

FIG. 10 is a block diagram showing the connections between various components of the variable height downdraft assembly shown in FIG. 1.

### DETAILED DESCRIPTION OF PREFERRED EMBODIMENTS

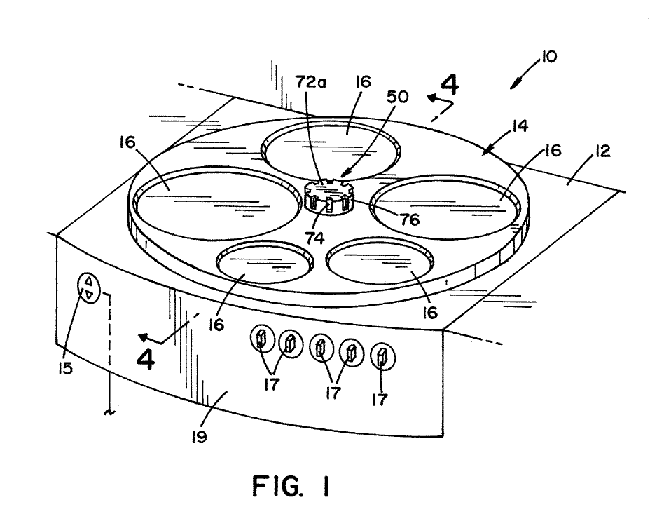

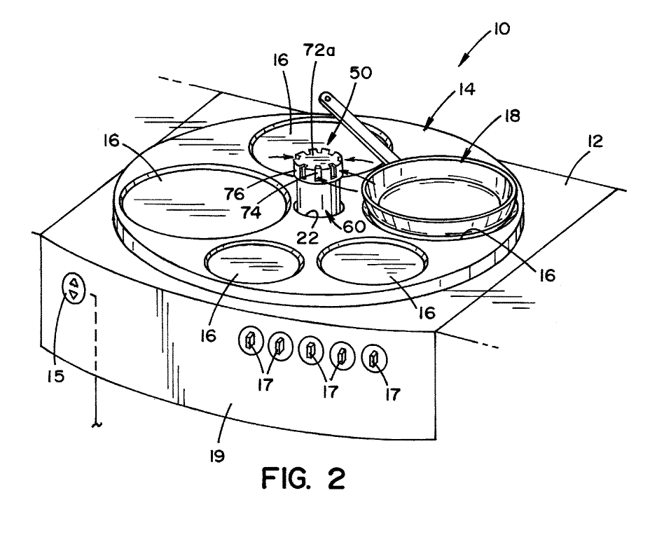

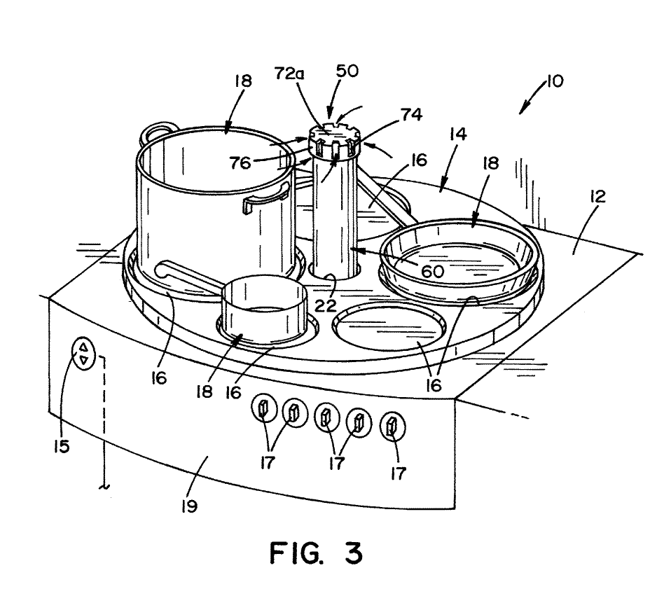

FIG. 1 shows a household appliance 10, e.g., a cooktop. In general, the appliance 10 includes a top panel 12 having a cooking hob 14 disposed thereon. The cooking hob 14 includes a plurality of heating zones 16 each configured to receive a cooking pot/pan 18 (seen in FIGS. 2 and 3) thereon. Each heating zone 16 is controlled by a control knob 17. In the embodiment shown, the control knobs 17 are disposed along a front panel 19 of the appliance 10. The control knobs 17 shown are conventional knobs that are rotated by a user to control the power level of the associated heating zone 16. It is also contemplated that buttons, switches or other known or conventional control devices may be used to control the operation of the heating zones 16.

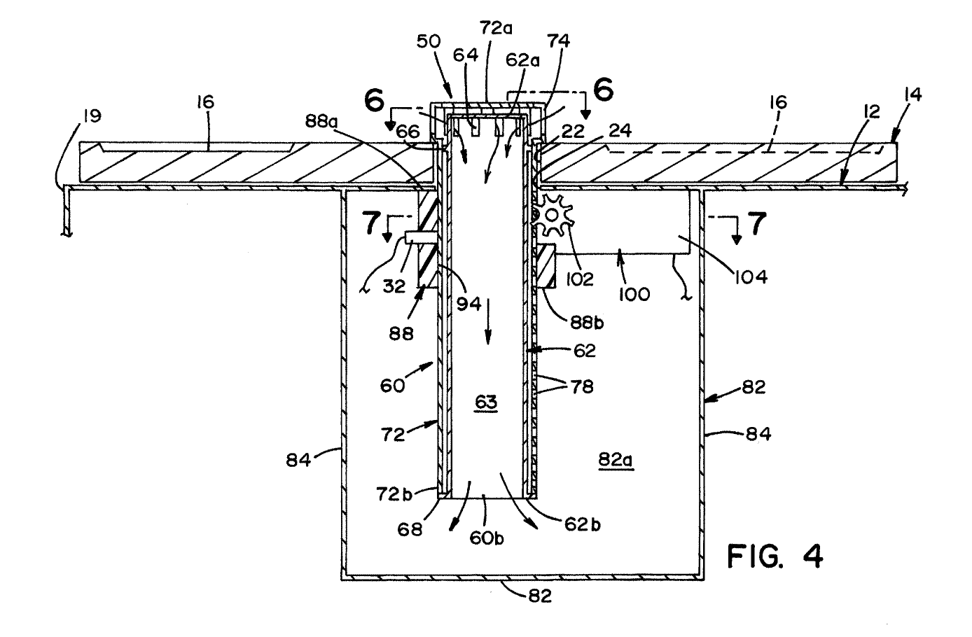

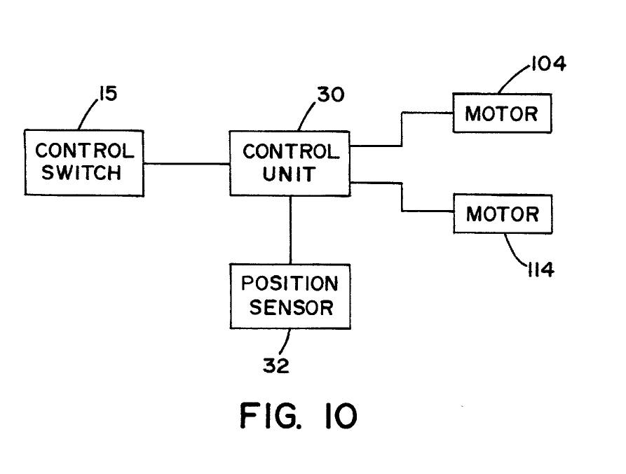

A hole 22 (FIG. 2) extends through a center of the cooking hob 14 and is dimensioned and positioned to align with a corresponding hole 24 (FIG. 4) extending through the top panel 12. A variable height downdraft assembly 50 extends through the holes 22, 24 formed in the cooking hob 14 and the top panel 12, respectively. A user input 15 is disposed on the front panel 19. The user input 15 is connected to a control unit 30 (shown in FIG. 10) for allowing a user to control the operation of the variable height downdraft assembly 50, as described in detail below. The control unit 30 may include a computer that is programmed to control the operation of the variable height downdraft assembly 50.

As seen in FIG. 4 the variable height downdraft assembly 50, in general, includes a movable duct 60, a housing 82, a drive assembly 100 and a blower assembly 110.

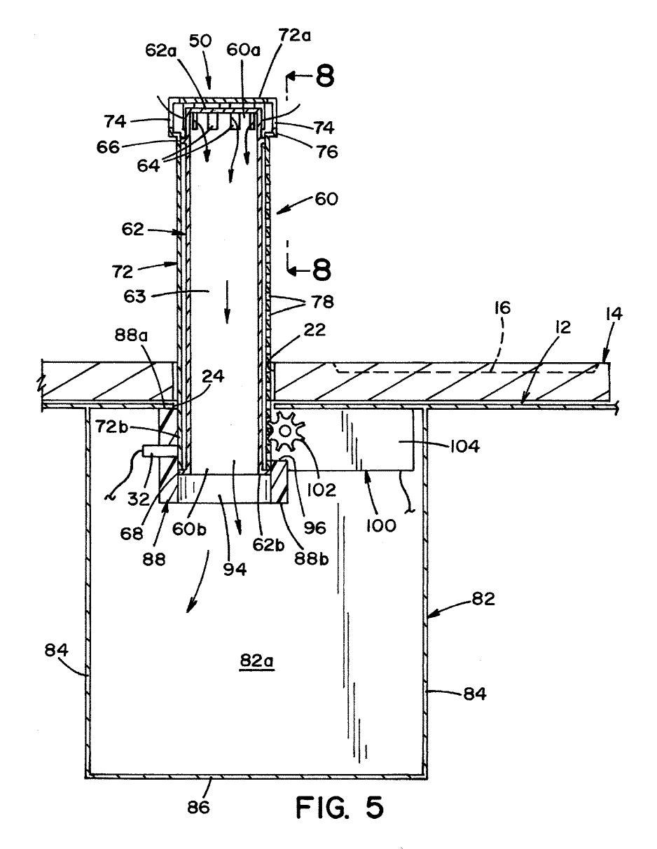

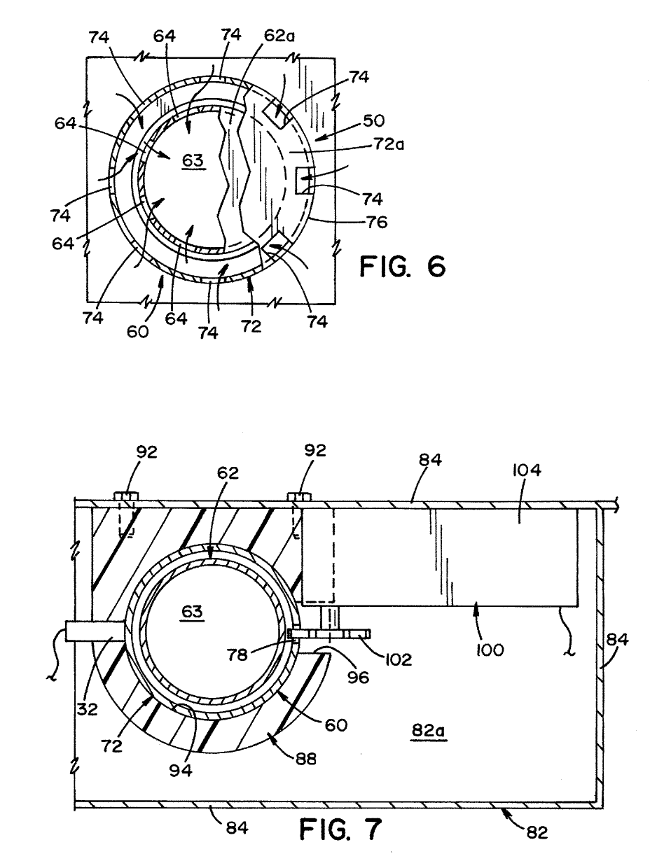

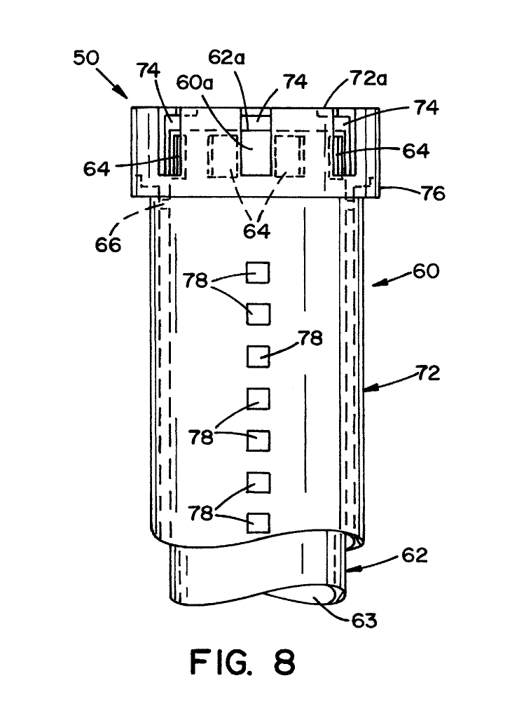

Referring now to FIGS. 4 and 5, the movable duct 60 is a generally tube-shaped element defining a flow passage that extends between an upper end 60a and a lower end 60b. The movable duct 60 includes an inner tube 62 and an outer tube 72. The inner tube 62 has an upper end 62a, a lower end 62b and an internal passageway 63 extending between the upper end 62a and the lower end 62b. A plurality of openings 64 are formed in the upper end 62a of the inner tube 62 and fluidly communicate with the passageway 63. In the embodiment shown, the plurality of openings 64 are rectangular in shape and are evenly spaced around an outer circumference of the upper end 62a of the inner tube 62. An upper flange 66 extends outwardly from the outer surface of the inner tube 62 near the upper end 62a. The lower end 62b includes a single opening that fluidly communicates with the passageway 63 in the inner tube 62. A lower flange 68 extends outwardly from the lower end 62b of the inner tube 62. The outer tube 72 is disposed around the inner tube 62 and axially aligns with the inner tube 62. The outer tube 72 includes an upper end 72a and a lower end 72b. A plurality of openings 74 (best seen in FIGS. 1-3) is formed in the upper end 72a of the outer tube 72. The upper end 72a of the outer tube 72 is enlarged to define a cap portion 76. The cap portion 76 has a diameter that is larger than the diameter of the remaining portion of the outer tube 72 such that the cap portion 76 defines a “stop” for the movable duct 60, as described in detail below. A plurality of spaced-apart openings 78 (best seen in FIG. 8) extend axially along a side wall of the outer tube 72 between the upper end 72a and the lower end 72b. The spaced-apart openings 78 are positioned and dimensioned to engage the drive assembly 100, as described in detail below.

The outer tube 72 is disposed around the inner tube 62 such that the lower end of the outer tube 72 rests on the lower flange 68 of the inner tube 62. In addition, the inner cylindrical surface of the outer tube 72 engages the outer periphery of the upper flange 66 of the inner tube 62.

The movable duct 60 includes the inner tube 62 and the outer tube 72. It is also contemplated that the movable duct 60 may include a single tube (not shown) wherein a plurality of openings are formed in an upper end of the single tube. In addition, a plurality of recesses, corresponding to the plurality of spaced-apart openings 78, may extend axially along the outer surface of the single tube. The plurality of recesses would be positioned and dimensioned to engage the drive assembly in a manner similar to that described below for the plurality of spaced-apart openings 78 in the outer tube 72. In this respect, the single tube would function in a manner similar to how the inner tube 62 and the outer tube 72 function. It is also contemplated that the plurality of spaced-apart openings 78 may be formed in a track that is attached to an outer surface of a single tube (not shown).

It is further contemplated that the movable duct 60 may include telescoping sections (not shown) that are nested together. The telescoping sections may move relative to each such that the distance between the upper end 60a of the movable duct 60 and the lower end 60b of the movable duct 60 can be varied. In addition, telescoping sections may allow the movable duct 60 to occupy less space under the top panel 12 of the appliance 10.

In the embodiment shown, the movable duct 60 is generally cylindrical in shape. It is contemplated that the movable duct 60 may have any other convenient shape, such as, but not limited to, rectangular and oval.

The housing 82 of the variable height downdraft assembly 50 (shown in FIGS. 4, 5 and 7) is attached to an underside of the top panel 12 of the appliance 10. The housing 82 includes side walls 84 and a lower wall 86. The housing 82 is position such that an internal cavity 82a of the housing 82 is in registry with the hole 24 in the top panel 12.

As shown in FIG. 7, fasteners 92 attach a bearing block 88 to one of the side walls 84 of the housing 82. A hole 94 extends through the bearing block 88 from a top surface 88a of the bearing block 88 to a bottom surface 88b of the bearing block 88. The bearing block 88 is positioned and dimensioned such that the hole 94 aligns with the hole 24 in the top panel 12. A front surface of the bearing block 88 is contoured. A notch 96 is formed in one side of the bearing block 88. The notch 96 extends to the hole 94 for allowing access to the hole 94 from the side of the bearing block 88.

The bearing block 88 may be made a material that allows the movable duct 60 to easily slide axially along the hole 94. In this respect, the bearing block 88 may be made of a plastic or other material with a low coefficient of friction. In the alternative, the bearing block 88 may include a bearing assembly (not shown) having a plurality of roller bearings that are designed for allowing the movable duct 60 to slide axially through the hole 94.

The holes 22, 24, 94 of the cooking hob 14, the top panel 12 and the bearing block 88, respectively, are positioned and dimensioned to align with each other. Holes 22, 24, 94 are dimensioned to allow the movable duct 60 to slide within the holes 22, 24, 94. The outer tube 72 of the movable duct 60 is positioned such that the plurality of spaced-apart openings 78 align with the notch 96 formed in the one side of the bearing block 88.

The drive assembly 100 is positioned to extend into the notch 96 in the bearing block 88 and to engage the spaced-apart openings 78 in the outer tube 72. Referring now to FIGS. 4, 5 and 7, the drive assembly 100 is shown. The drive assembly 100 includes a gear 102 that is driven by a motor 104. The gear 102 includes a plurality of teeth that are dimensioned to engage the plurality of spaced-apart openings 78 formed in the outer tube 72. The gear 102 can be a spur gear that is dimensioned to engage the plurality of spaced-apart openings 78. However, it is contemplated that other gears, such as worm gears, helical gears, bevel gears, etc., may also be used.

The motor 104 is attached to the gear 102 for turning the gear 102. The motor 104, in turn, is connected to the control unit 30 that controls the operation of the motor 104. The motor 104 and gear 102 are designed such that rotation of the gear 102 causes the movable duct 60 to move in a vertical direction relative to the upper surface of the cooking hob 14 of the appliance 10. As noted above, the user input 15 is attached to the front panel 19 of the appliance 10. Upon actuation of the user input 15 by a user, the control unit 30 causes the motor to turn in a direction that corresponds to movement of the movable duct 60 in the desired direction.

A position sensor 32 (see FIGS. 4, 5 and 7) is attached to the bearing block 88 to determine the vertical position of the upper end 60a of the movable duct 60 relative to the cooking hob 14. The position sensor 32 may be a Hall effect sensor or another known position sensor that detects position or motion of the movable duct 60.

It is contemplated that, instead of the position sensor 32, a Hall effect sensor (not shown) may be disposed proximate the gear 102 to detect rotation of the gear 102 and provide a signal to the control unit 30 indicative of the rotation of the gear 102, e.g., the speed of the gear, the number of teeth that pass the sensor, etc. Based on the foregoing signal, the control unit 30 may be programmed to determine the position of the movable duct 60. It is also contemplated that several limit switches (not shown) could be placed at several distinct locations relative to the movable duct 60 to provide signals to the control unit 30 when the movable duct 60 is one of the predetermined positions. It is also contemplate that the motor 104 may be a stepper motor wherein the control unit 30 determines the position of the movable duct 60 based on a signal from the motor 104.

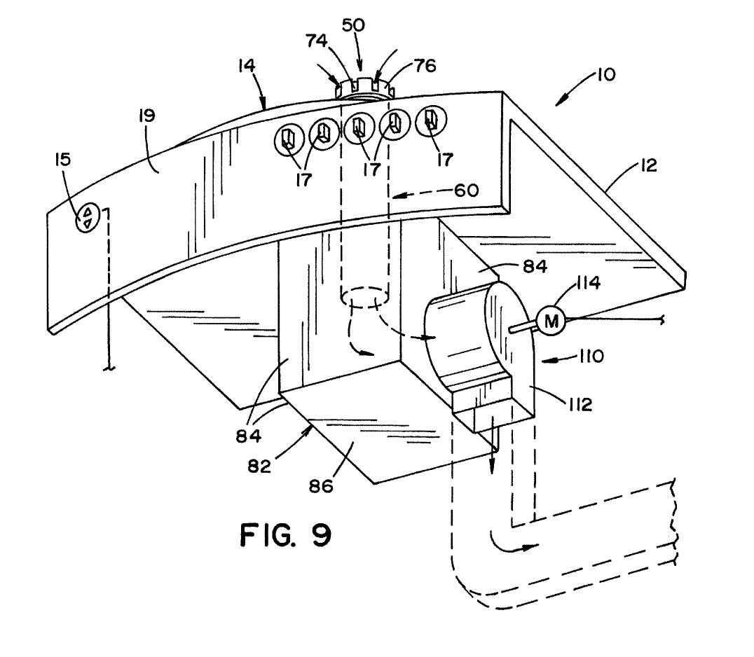

Referring now to FIG. 9, a blower assembly 110 is attached to one side wall 84 of the housing 82. A hole (not shown) is formed in the housing 82 to allow the blower assembly 110 to fluidly communicate with the internal cavity 82a of the housing 82 and the passageway 63 of the inner tube 62 of the movable duct 60. It is also contemplated that the blower assembly 110 may be directly connected to the lower end 60b of the movable duct 60. The blower assembly 110 includes a blower 112 that is driven by a motor 114. The motor 114, in turn, is controlled by the control unit 30. Operation of the motor 114 causes the blower 112 to turn and to draw air through the movable duct 60. In particular, air is drawn from the region proximate the upper end 60a of the movable duct 60, through the plurality of openings 74 in the outer tube 72, through the plurality of openings 64 in the inner tube 62, along the passageway 63 in the inner tube 62, into the internal cavity 82a of the housing 82 and to the blower 112. An outlet end of the blower 112 is optionally attached to a duct for conveying the air drawn through the movable duct 60 to a location remote from the appliance 10.

The variable height downdraft assembly 50 will now be described in operation. FIG. 1 shows the movable duct 60 in a stored, fully retracted position. In this stored position an underside of the cap portion 76 of the outer tube 72 engages a top surface of the cooking hob 14 (see FIG. 4). The user input 15 on the front panel 19 of the appliance 10 is designed such that a user may selectively place the upper end 60a of the movable duct 60 at a desired height relative to the upper surface of the cooking hob 14. For example, a user may input a desired height, in inches or some other convenient unit of measurement, and the control unit 30 may be programmed to turn the motor 104, as needed, to place the movable duct 60 at the requested height above the cooking hob 14. As shown in FIGS. 2 and 3, the height of the movable duct 60 may be selected based on the height of the cooking pots/pans that are disposed on the plurality of heating zones 16.

FIG. 5 shows the movable duct 60 in an uppermost, fully extended position. In this position, the upper end 60a of the movable duct 60 is disposed at its maximum height relative to the upper surface of the cooking hob 14. It is contemplated that a stop (not shown) may be disposed on an outer surface of the outer tube 72 to physically limit the distance that the upper end 60a of the movable duct 60 may be extended above the upper surface of the cooking hob 14. Alternatively, the control unit 30 may be programmed to receive a signal from the position sensor 32 indicative of the movable duct 60 reaching its maximum height. At this point, the control unit 30 may allow the movable duct 60 to move only in a downward direction.

It is also contemplated that the user input 15 may have an “UP” button and a “DOWN” button such that actuation of one of the buttons by the user causes the control unit 30 to move the movable duct 60 in the selected direction. Upon release of the button, the control unit 30 would cause the movable duct to stop moving.

In the embodiment shown, the drive assembly 100 includes the motor 104 and the gear 102. However, it is contemplated that other means of moving the movable duct 60, such as hydraulic or pneumatic cylinders, may be used.

It is also contemplated that the control unit 30 may control the operation of the blower assembly 110. The user input 15 may include a separate button that causes the control unit 30 to energize the motor 114, thereby causing the blower 112 to draw air through the movable duct 60. Alternatively, it is contemplated that the motor 114 may be energized automatically by the control unit 30 when a user actuates the user input 15 to move the movable duct 60 from the stored position to a desired height.

An illustrative embodiment has been described, hereinabove. It will be apparent to those skilled in the art that the above apparatuses and methods may incorporate changes and modifications without departing from the scope of this disclosure. The invention is therefore not limited to particular details of this disclosure except to the extent that the following claims are necessarily so limited.

What is claimed is:

1. A household appliance including a heating element at an upper surface of the appliance, and a variable height downdraft vent assembly movable relative to the upper surface of the appliance, the vent assembly comprising:
a duct defining a flow passage between an upper end and a lower end thereof, the duct movable in a vertical direction relative to the upper surface of the appliance; and
a drive assembly for engaging the duct and configured to position the upper end of the duct at a user-selected variable height relative to the upper surface of the appliance.

2. The household appliance of claim 1, said duct including an inner tube and an axially aligned outer tube.

3. The household appliance of claim 2, said drive assembly including a gear for engaging the outer tube of the duct.

4. The household appliance of claim 1, further comprising a control unit for controlling the operation of the drive assembly.

5. The household appliance of claim 4, the control unit programmed to position the duct at said user-selected variable height.

6. The household appliance of claim 4, further comprising a position sensor programmed to provide a signal to the control unit indicative of the position of the duct relative to the upper surface of the appliance.

7. A method of operating the household appliance of claim 1, comprising:
receiving a first signal corresponding to a user input for a user-selected height for the upper end of the duct relative to the upper surface of the appliance; and
operating the drive assembly to position the upper end of the duct at the user-selected height.

8. The method according to claim 7, said first signal being based on a value corresponding to the user-selected height entered by the user via an input device.

9. The method according to claim 7, said first signal being based on a direction of movement for said duct selected by the user via an input device.

10. The method according to claim 7, further comprising receiving a second signal from a position sensor indicative of a position of the upper end of the duct relative to the upper surface of the appliance, and operating said drive assembly at least in part based on said second signal.
